(19) United States
(12) Patent Application Publication
(10) Pub. No.: US 2016/0377676 A1
(43) Pub. Date: Dec. 29, 2016

(54) INTEGRATED CIRCUIT INCLUDING OVERLAPPING SCAN DOMAINS

(71) Applicant: Freescale Semiconductor, Inc., Austin, TX (US)

(72) Inventors: Roy Menahem Shor, Tel-Aviv (IL); Asher Berkovitz, Kiryat Ono (IL); Shlomi Sde-Paz, Kadima (IL)

(21) Appl. No.: 14/747,924

(22) Filed: Jun. 23, 2015

(51) Int. Cl. G01R 31/3177

(52) U.S. Cl. CPC G01R 31/3177

(57) ABSTRACT

An integrated circuit includes overlapping scan domains, wherein at least one scan domain of the integrated circuit includes some, but not all, of the synchronous logic elements, logic gates, and signal paths of a different scan domain. Each scan domain includes a scan wrapper to receive test patterns generated to test the logic mix for that domain. The test patterns are propagated through the logic mix of the scan domain to generate corresponding output patterns, which are compared to expected results for that scan domain. By overlapping the scan domains, test coverage of the integrated circuit can be increased without substantially increasing testing time. The test patterns applied to the integrated circuit can be pruned to remove duplicate patterns generated for overlapping scan domains.

### BACKGROUND

Field of the Disclosure

The present disclosure relates generally to integrated circuits and more particularly to scan domains for integrated circuits.

Description of the Related Art

Due to their complexity, integrated circuits are extensively tested prior to leaving a manufacturer's facility or prior to being incorporated into an electronic device. One common testing technique is scan testing, wherein a tester applies a set of test patterns to input nodes of the integrated circuit, applies a clock signal to propagate the test patterns through the synchronous logic elements and logic gates of the integrated circuit to generate a set of output patterns, and compares the output patterns to a set of expected results. However, testing all of the synchronous logic elements and logic gates of the integrated circuit with a set of test patterns can require an excessive amount of time and requires generating a complex set of test patterns. Accordingly, integrated circuits are often tested by dividing the logic gates and synchronous logic elements of the integrated circuit into separate and independent subsets, referred to as scan domains. Each scan domain includes a scan wrapper where test patterns for the scan chain are input for application to the synchronous logic elements and logic gates of the scan domain. The test patterns propagate through the logic of the scan domain to generate corresponding output patterns for comparison to expected results. However, while dividing the integrated circuit into separate and independent scan domains can simplify the scan testing process, it frequently fails to provide test coverage for all of the synchronous logic elements, logic devices, and associated signal paths of the integrated circuit.

### BRIEF DESCRIPTION OF THE DRAWINGS

The present disclosure may be better understood, and its numerous features and advantages made apparent to those skilled in the art by referencing the accompanying drawings. The use of the same reference symbols in different drawings indicates similar or identical items.

FIG. 1 is a block diagram of an integrated circuit employing at least two overlapping scan domains in accordance with at least one embodiment of the present disclosure.

FIG. 2 is a block diagram of an integrated circuit employing at least three overlapping scan domains in accordance with at least one embodiment of the present disclosure.

FIG. 3 is a block diagram of an integrated circuit employing at least three overlapping scan domains, wherein all three of the scan domains overlap in accordance with at least one embodiment of the present disclosure.

FIG. 4 is a flow diagram of a method of testing an integrated circuit having overlapping scan domains in accordance with at least one embodiment of the present disclosure.

### DETAILED DESCRIPTION

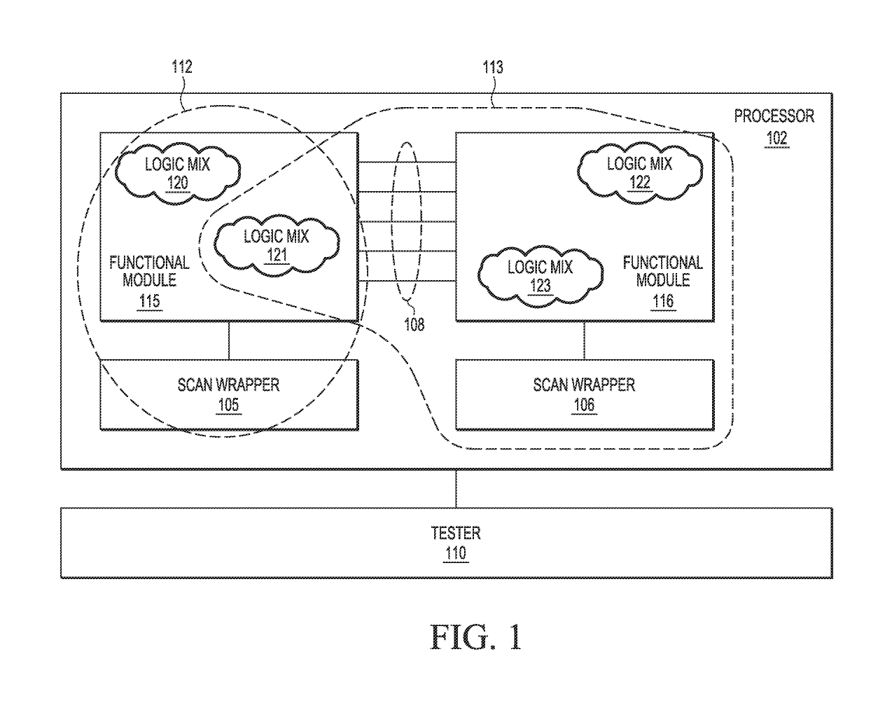

FIGS. 1-4 illustrate example integrated circuits having overlapping scan domains, and techniques for testing such integrated circuits. The scan domains overlap in that a given scan domain of an integrated circuit can include some, but not all, of the synchronous logic elements, logic gates, and signal paths (collectively referred to as the “logic mix”) of a different scan domain. Each scan domain includes a scan wrapper to receive test patterns generated to test the logic mix for that domain. The test patterns are propagated through the logic mix of the scan domain to generate corresponding output patterns, which are compared to expected results for that scan domain. Because the scan domains for the integrated circuit overlap, test coverage for the integrated circuit is increased without significantly increasing the time required to test the integrated circuit.

To illustrate, an integrated circuit can be a processor that includes different functional modules, with each functional module designed to carry out a specified set of functions. For example, one functional module may be a processor core and another functional module a memory controller. Conventionally each functional module is defined as its own scan domain and is tested separately from the other functional modules and corresponding scan domains of the processor. Because the functional modules are in separate scan domains, the test results for each scan domain depend only on the logic mixes in the corresponding functional module. Accordingly signal paths and potentially some logic elements between the functional modules are not tested, and errors in those paths and logic elements are not detected by the testing process. By employing overlapping scan domains that include logic mixes from different functional modules, these signal paths and logic elements can be tested, thereby improving test coverage and detection of design or manufacturing errors. In addition, the scan domains can be overlapped so that the size of each overlapping scan domain is only slightly larger than it would be if it did not overlap, for example by only overlapping one or two logic mixes between scan domains. This provides increased test coverage without significantly increasing test time or complexity.

FIG. 1 illustrates an integrated circuit testing system 100 to test a processor 102 having overlapping scan domains 112 and 113 in accordance with at least one embodiment of the present disclosure. The processor 102 is an integrated circuit, and is a general-purpose or application-specific processor generally configured to execute sets of instructions (e.g., computer programs) to carry out specified tasks. The processor 102 can be incorporated into any of a variety of electronic devices, including consumer devices such as a desktop computer, laptop computer, tablet, smartphone, vehicle (e.g., an automobile), and the like. It will be appreciated that although the integrated circuit testing system 100 is described with respect to the example context of the processor 102, the overlapping scan domain techniques described herein can be applied to any of a variety of integrated circuits, including memory circuits, switch fabrics, hardware controllers, and the like.

The processor 102 is connected to a tester 110. The tester 110 is a computer device, such as a workstation, and associated hardware generally configured to generate test patterns for the processor 102, apply those test patterns to the scan domains 112 and 113, obtain the corresponding test results from each scan domain, and compare the test results to a set of expected results to identify any errors. The tester 110 may include other hardware and software modules to support these testing functions. For example, in at least one embodiment the tester 110 includes hardware to generate a test clock signal for application to the processor 102, which uses the test clock signal to synchronize propagation of the test patterns through the logic mixes of the scan domains 112 and 113. The tester 110 may further include software and hardware modules to analyze test results, including identification of particular aspects or functions of the processor 102 that are likely generating any detected errors, software and hardware modules to present test results and analysis to a user or another computer device, and the like.

The processor 102 includes functional modules 115 and 116 connected to each other via a set of signal lines 108. The functional modules 115 and 116 are arrangements of logic elements, including logic gates and synchronous logic elements, that perform specified functions during normal “in-situ” operation of the processor 102. In at least one embodiment, each of the functional modules 115 and 116 is separately and independently specified and designed during the design of the processor 102, then integrated together as part of the design process. Accordingly, each functional module may be separately described in a design file (not shown) for the processor 102, with the behavior of each functional module separately specified in the design file as sets of expected inputs and corresponding outputs to the functional module. Examples of functional modules include processor cores, memory controllers, input/output controllers, device interfaces, caches, and the like.

Each of the functional modules 115 and 116 includes logic mixes (e.g., logic mixes 120 and 121 of functional module 115 and logic mixes, 121, 122 and 123 of functional module 116). Each logic mix is a connected set of one or more synchronous logic elements, logic gates, and the like. In at least one embodiment, one or more of the logic mix includes at least one set of synchronous logic elements (e.g., latches) to store input data for the logic mix, at least one set of logic elements to store output data for the logic mix, and logic gates connected between the input and output sets to execute logical operations on the input data thereby transforming it to the output data.

The scan domains 112 and 113 represent collections of logic mixes that are all tested by a common set of test patterns. To illustrate, each of the scan domains 112 and 113 includes a corresponding scan wrapper (e.g., scan wrapper 105 of scan domain 112 and scan wrapper 106 of scan domain 113). Each scan wrapper includes hardware to accept test patterns from the tester 110, apply those test patterns to one or more inputs of the logic mixes of the scan domain, and to store resulting output patterns generated by the logic mixes. In at least one embodiment, each scan wrapper includes a set of input latches connected so that the tester 110 can serially or in parallel store a test pattern at the input latches. In response to the tester 110 applying a clock signal to the input latches and logic mixes of a scan domain, the scan domain applies the test pattern as a set of input signals to the logic mixes. Based on the configuration of the logic elements of the logic mixes, the logic mixes generates output data, referred to as a test output, stored at a set of output latches of the scan wrapper. After a specified number of clock signals, the tester 110 accesses the test outputs at each scan wrapper for comparison to a set of expected test results. If a test output based on a particular test pattern differs from an expected test result, the tester 110 can indicate a potential error in the operation, manufacture, or design of the processor 102.

The test outputs generated by a scan domain are based on the behavior of the logic mixes and associated signal lines of the scan domain (e.g., interconnects, vias, conductive traces, wires, and the like that carry electrical signals between logic elements). Accordingly, the test outputs of a scan domain are referred to as providing provide test coverage for the logic mixes and signal lines of the scan domain, because the test outputs indicate the behavior of the logic mixes and signal lines that generated the test outputs. The processor 102 includes overlapping scan domains in order to increase the overall test coverage for the device. As used herein, the term overlapping is defined to mean that a scan domain includes some, but not all, of the logic gates and synchronous logic elements of another scan domain. For example, the scan domains 112 and 113 are overlapping because they include some, but not all, of the same logic mixes. In particular, in the illustrated example the scan domain 112 and the scan domain 113 both include logic mix 121. Accordingly, the behavior of logic mix 121 is indicated both by the test outputs generated by the scan domain 112 and test outputs generated by the scan domain 113. In addition, the logic mix 121 is connected to one or more of the logic mixes 122 and 123 via the signal lines 108. The test outputs for the scan domain 113 therefore provide test coverage for the signal lines 108. Conventionally, each of the functional modules 115 and 116 would be arranged in independent, non-overlapping scan domains, such that no test outputs would provide coverage of the signal lines 108. Thus, by overlapping the scan domains 112 and 113, test coverage for the processor 102 is increased. In at least one embodiment, the scan domains 112 and 113 overlap by a relatively small number of logic mixes, and therefore a correspondingly small number of logic gates and synchronous logic elements. The overlapping scan domains therefore increase test coverage without substantially increasing test time. For example, in at least one embodiment the overlapping scan domains 112 and 113 can be formed from the logic elements of functional module 116 and a minimum number of logic elements of functional module 115 to provide test coverage for the signal paths between the functional elements, such as signal lines 108.

In at least one embodiment, the tester 110 generates the test patterns for application to the scan domains of the processor 102. For example, the tester 110 may include software or hardware to perform one or more Automatic Test Pattern Generation (ATPG) techniques to generate test patterns for each scan domain. For some processor designs, similar test patterns applied to overlapping scan domains may stimulate or otherwise test similar logic mixes and signal lines of the processor. That is, the similar test patterns provide the same or similar test coverage. Accordingly, to reduce test time and complexity, as well as the amount of space required to store test patterns, the tester 110 can prune the test patterns for a given scan domain by removing those test patterns that match the test patterns for an overlapping scan domain. Thus, for example, the tester 110 can generate one set of test patterns for scan domain 112 and another set of test patterns for scan domain 113. The tester 110 can then compare the two test pattern sets, and remove from one of the sets (e.g., the set of test patterns for scan domain 113) any matching test patterns. The tester 110 can then apply the corresponding test pattern sets to each scan domain as described above.

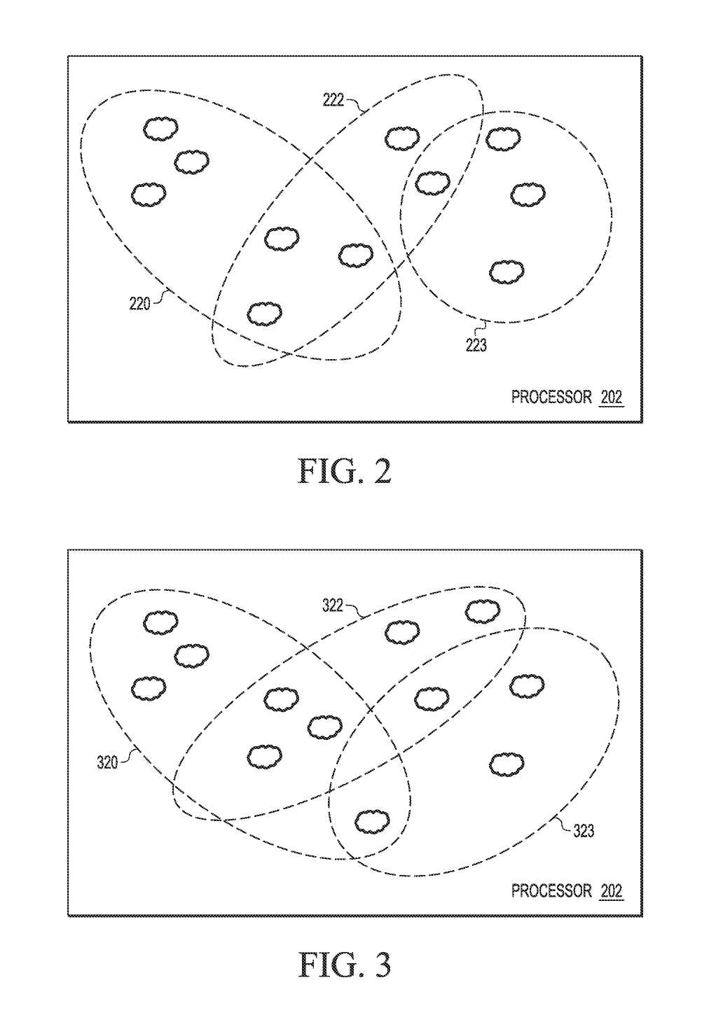

A functional unit can have multiple overlapping scan domains. For example, FIG. 2 illustrates a processor 202 including scan domains 220, 222, and 223 in accordance with at least one embodiment of the present disclosure. The scan domain 222 overlaps with the scan domains 220 and 223, while the scan domains 220 and 223 are entirely independent of each other. That is, the scan domains 220 and 223 do not include any of the same logic mixes, while the scan domain 222 includes some, but not all, of the logic mixes of scan domain 220 and some, but not all, of the logic mixes of scan domain 223.

FIG. 3 illustrates a processor 302 having overlapping scan domains 320, 322, and 323 in accordance with at least one embodiment of the present invention. In the example of FIG. 3, the scan domains 320, 322, and 323 all overlap with each other. Thus, scan domain 320 includes some, but not all, of the logic mixes of scan domain 322 and some, but not all, of the logic mixes of scan domain 323. In addition, scan domain 322 includes some, but not all, of the logic mixes of scan domain 323. In addition, while in the depicted example the scan domains 320, 322, and 323 do not include any logic mixes in common, in at least one embodiment the same logic mix can be included in three or more scan domains.

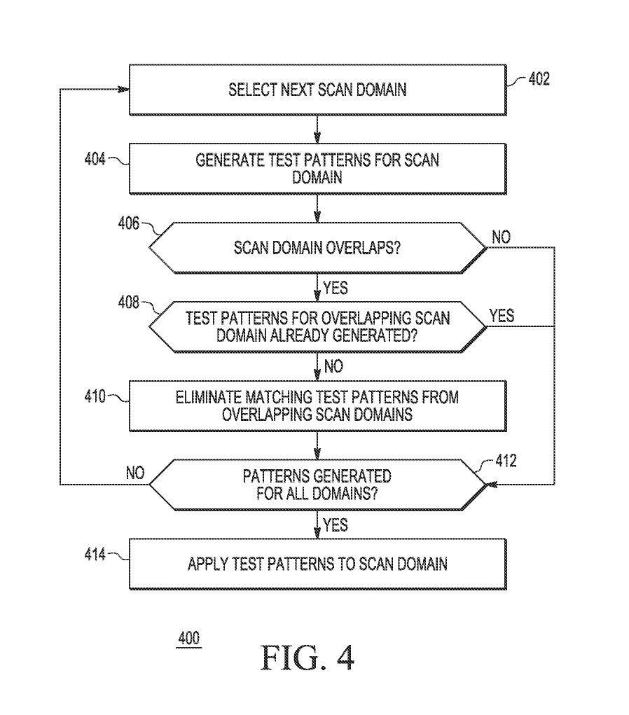

FIG. 4 illustrates a flow diagram of a method 400 of testing a processor or other functional unit having overlapping scan domains in accordance with at least one embodiment of the present disclosure. The method 400 is described with respect to an example implementation of the processor 102 and the tester 110 of FIG. 1. At block 402, the tester 110 selects the initial scan domain from a list of scan domains of the processor 102. The list of scan domains can be specified in a design file for the processor 102, via a dedicated list of scan domains for a processor design, manually supplied by a user, and the like.

At block 404, the tester 110 generates a set of test patterns for the selected scan domain. In at least one embodiment, each test pattern is a binary number of a size corresponding to the input elements of the scan wrapper for the scan domain. For example, the scan wrapper 105 may be configured to receive test patterns of 32-bit binary numbers, and the tester 110 therefore generates test patterns of that size. The test patterns can be generated using ATPG techniques, such as D algorithms, path-oriented decision making (PODEM) algorithms, fan-out oriented algorithms, pseudo-random test generation algorithms, spectral algorithms such as wavelet automatic spectral pattern (WASP) algorithms, and the like, or any combination thereof.

At block 406, the tester 110 determines whether the selected scan domain overlaps with another scan domain of the processor 102. In at least one embodiment, the design file or other data file that lists the scan domains of the processor 102 can include an entry for each scan domain, with each entry including a field indicating with which other scan domains the scan domain overlaps. In another embodiment, the data file lists the logic mixes included in each scan domain, and the tester 110 compares the list of logic mixes for the selected scan domain to the lists of other scan domains to identify any overlap. If the selected scan domain does not overlap with another scan domain, the method flow proceeds to block 412, described below. If the selected scan domain does overlap with one or more other scan domains (referred to for purposes of description as the overlapping scan domains), the method flow proceeds to block 408 and the tester determines whether test patterns for one or more of the overlapping scan domains have already been generated. If not, the method flow proceeds to block 412, described below.

If, at block 408, the tester 110 determines that one or more of the overlapping scan domains have already been tested, the method flow proceeds to block 410 and the tester 110 compares the set of test patterns generated for the selected scan domain to the sets of test patterns for the overlapping scan domains. The tester 110 removes from the set of test patterns for the selected scan domain any test patterns already included in the test pattern sets for the overlapping scan domains. The matching test patterns are likely to test the logic mixes in common between the scan domains in the same or similar ways. That is, the matching test patterns provide similar test coverage of the processor 102. Accordingly, by eliminating the matching test patterns from the selected set of test patterns, the tester 110 can reduce testing time for the processor 102 while maintaining the same or similar level of test coverage.

At block 412 the tester 110 determines whether it has generated test pattern sets for all scan domains of the processor 102. If not, the method flow returns to block 402 and the tester 110 selects the next scan domain from the list. If the tester 110 has generated test patterns for all of the scan domains of the processor 102, the method flow proceeds to block 414 and the tester 110 applies each set of test patterns to its corresponding scan domain. In response, each scan domain generates a corresponding set of output patterns, which the tester 110 records and compares to an expected set of test results to identify errors at the processor 102.

In some embodiments, certain aspects of the techniques described above may implemented by one or more processors of a processing system executing software. The software comprises one or more sets of executable instructions stored or otherwise tangibly embodied on a non-transitory computer readable storage medium. The software can include the instructions and certain data that, when executed by the one or more processors, manipulate the one or more processors to perform one or more aspects of the techniques described above. The non-transitory computer readable storage medium can include, for example, a magnetic or optical disk storage device, solid state storage devices such as Flash memory, a cache, random access memory (RAM) or other non-volatile memory device or devices, and the like. The executable instructions stored on the non-transitory computer readable storage medium may be in source code, assembly language code, object code, or other instruction format that is interpreted or otherwise executable by one or more processors.

A non-transitory computer readable storage medium may include any storage medium, or combination of storage media, accessible by a computer system during use to provide instructions and/or data to the computer system. Such storage media can include, but is not limited to, optical media (e.g., compact disc (CD), digital versatile disc (DVD), Blu-Ray disc), magnetic media (e.g., floppy disc, magnetic tape, or magnetic hard drive), volatile memory (e.g., random access memory (RAM) or cache), non-volatile memory (e.g., read-only memory (ROM) or Flash memory), or microelectromechanical systems (MEMS)-based storage media. The computer readable storage medium may be embedded in the computing system (e.g., system RAM or ROM), fixedly attached to the computing system (e.g., a magnetic hard drive), removably attached to the computing system (e.g., an optical disc or Universal Serial Bus (USB)-based Flash memory), or coupled to the computer system via a wired or wireless network (e.g., network accessible storage (NAS)).

Note that not all of the activities or elements described above in the general description are required, that a portion of a specific activity or device may not be required, and that one or more further activities may be performed, or elements included, in addition to those described. Still further, the order in which activities are listed are not necessarily the order in which they are performed. Also, the concepts have been described with reference to specific embodiments. However, one of ordinary skill in the art appreciates that various modifications and changes can be made without departing from the scope of the present disclosure as set forth in the claims below. Accordingly, the specification and figures are to be regarded in an illustrative rather than a restrictive sense, and all such modifications are intended to be included within the scope of the present disclosure.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims. Moreover, the particular embodiments disclosed above are illustrative only, as the disclosed subject matter may be modified and practiced in different but equivalent manners apparent to those skilled in the art having the benefit of the teachings herein. No limitations are intended to the details of construction or design herein shown, other than as described in the claims below. It is therefore evident that the particular embodiments disclosed above may be altered or modified and all such variations are considered within the scope of the disclosed subject matter. Accordingly, the protection sought herein is as set forth in the claims below.

1. An integrated circuit comprising:
a first scan domain comprising a first plurality of logic elements and a first scan wrapper to apply a first set of test patterns to the first plurality of logic elements; and
a second scan domain comprising a second plurality of logic elements and a second scan wrapper to apply a second set of test patterns to the second plurality of logic elements, the second scan domain overlapping with the first scan domain.

2. The integrated circuit of claim 1 wherein the first scan domain includes input/output signal lines between a first functional module of the integrated circuit and a second functional module of the integrated circuit, and wherein the second scan domain does not include the input/output signal lines.

3. The integrated circuit of claim 2, wherein the second scan domain includes the first functional module of the integrated circuit and does not include the second functional module.

4. The integrated circuit of claim 1, further comprising:
a third scan domain comprising a third plurality of logic elements and a third scan wrapper to apply a third set of test patterns to the third plurality of logic elements, the third scan domain overlapping with the first scan domain.

5. The integrated circuit of claim 4, wherein the third scan domain overlaps with the second scan domain.

6. The integrated circuit of claim 5, wherein the third scan domain does not overlap with the second scan domain.

7. The integrated circuit of claim 1, wherein:
the first scan domain comprises the logic elements of a first functional module of the integrated circuit and a minimum number of logic elements of a second functional module of the integrated circuit to provide test coverage of signal paths between the first functional module and the second functional module.

8. The integrated circuit of claim 1, wherein the integrated circuit is incorporated in a consumer device.

9. An integrated circuit, comprising:
a first scan domain including a portion of a first functional module, a portion of a second functional module, and input/output signal lines between the first functional module and the second functional module; and
a second scan domain that overlaps with the first scan domain, the second scan domain including the portion of the first functional module and excluding the portion of the second functional module.

10. The integrated circuit of claim 9, wherein the second scan domain does not include the input/output signal lines between the first functional module and the second functional module.

11. The integrated circuit of claim 9, wherein the first scan domain includes a first scan wrapper to apply a first set of test patterns to the first scan domain.

12. The integrated circuit of claim 11, wherein the second scan domain includes a second scan wrapper to apply a second set of test patterns to the second scan domain, the second set of test patterns based on the first set of test patterns.

13. A method, comprising:
applying a first set of test patterns to a first scan domain of an integrated circuit, the first scan domain comprising a first plurality of logic elements; and
applying a second set of test patterns to a second scan domain of the integrated circuit, the second scan domain comprising a second plurality of logic elements, the second scan domain overlapping with the first scan domain.

14. The method of claim 13, further comprising:
generating the second set of test patterns based on the first set of test patterns.

15. The method of claim 14, wherein generating the second set of test patterns comprises:
generating a third set of test patterns; and
generating the second set of test patterns by removing from the third set of test patterns those test patterns that match test patterns of the first set of test patterns.

16. The method of claim 13, wherein the first scan domain includes logic elements not included in the second scan domain and the second scan domain includes logic elements not included in the first scan domain.

17. The method of claim 13 wherein the first scan domain includes input/output signal lines between a first functional module of the integrated circuit and a second functional module of the integrated circuit, and wherein the second scan domain does not include the input/output signal lines.

18. The method of claim 17, wherein the second scan domain includes the first functional module of the integrated circuit and does not include the second functional module.

19. The method of claim 13, further comprising:
applying a third set of test patterns to a third scan domain comprising a third plurality of logic elements, the third scan domain overlapping with the first scan domain.

20. The method of claim 19, wherein the third scan domain overlaps with the second scan domain.
